(19) United States
(12) Patent Application Publication
(10) Pub. No.: US 2025/0389749 A1
(43) Pub. Date: Dec. 25, 2025

(54) METHOD AND SYSTEM FOR CALCULATING SYSTEM INERTIA BASED ON SLIDING WINDOW AT MOMENT OF FAULT OCCURRENCE

(71) Applicant: Nanjing SAC Power Grid Automation Co., Ltd, Nanjing (CN)

(72) Inventors: Cong LI, Nanjing (CN); Bing HU, Nanjing (CN); Feng KANG, Nanjing (CN); Dong CHEN, Nanjing (CN); Yinian QI, Nanjing (CN); Changsong QIN, Nanjing (CN); Dong YANG, Nanjing (CN)

(73) Assignee: Nanjing SAC Power Grid Automation Co., Ltd, Nanjing (CN)

(21) Appl. No.: 18/889,593

(22) Filed: Sep. 19, 2024

(30) Foreign Application Priority Data
Jun. 24, 2024 (CN) 2024108171153

(51) Int. Cl. G01P 15/08; G01R 31/34

(52) U.S. Cl. CPC G01P 15/08; G01R 31/343

(57) ABSTRACT

Disclosed are a method and system for calculating system inertia based on a sliding window at a moment of fault occurrence. The method includes: acquiring a frequency of each bus of a power system, active data of tie lines, and an active power output of a generator unit, and calculating a capacity of the power system; filtering the frequency of each bus, a bus voltage and the active power output of the generator unit; calculating a frequency change rate of the power system at each node, and determining a moment of fault occurrence; calculating a voltage fluctuation index of each bus; calculating a frequency change rate of each window; calculating an inertia change curve of the power system; and obtaining inertia of the power system according to the inertia change curve of the power system.

### CROSS-REFERENCE TO RELATED APPLICATIONS

The application claims priority to Chinese patent application No. 2024108171153, filed on Jun. 24, 2024, the entire contents of which are incorporated herein by reference.

### TECHNICAL FIELD

The present disclosure relates to the technical field of security and stability control of power systems, and particularly relates to a method and system for calculating system inertia based on a sliding window at a moment of fault occurrence.

### BACKGROUND

Future development of power systems, such as relatively large generator units, virtual power plants and grid connection facilities of distributed renewable energy, will lead to significant changes in power system inertia. At present, with the help of a Supervisory Control and Data Acquisition (SCADA) system, inertia of a power system is calculated by counting rotational inertia of all grid-connected synchronous generator units, and the inertia of the power system is considered to be a constant. A monitoring range cannot cover non-regulated generator units, loads and other potentially new forms of inertia in the future, such that an inertia value is underestimated and accuracy is not high. During operation of a power system, when inertia of the power system is significantly lower than a desired value designed in the planning stage, deterministic protection and control methods in the prior art maybe cannot ensure stability of the power system.

In recent years, many scholars and research institutions both at home and abroad have conducted researches on online inertia assessment and frequency characteristic analysis, and some research results have been applied to actual power grids, which can be summarized as follows from three perspectives:
(1) With the help of the SCADA system, inertia of a power system is calculated by counting rotational inertia of all grid-connected synchronous generator units, and the inertia of the power system is considered to be a constant. At present, according to conventional schemes, this method in (1) is usually adopted for online monitoring of power system inertia levels. A monitoring range cannot cover non-regulated generator units, loads and other potentially new forms of inertia in the future, such that an inertia value is underestimated and accuracy is not high.
(2) With the help of a wide-area measurement power system, power system inertia and regional inertia are assessed based on power, frequencies and other data of the power system measured after a large disturbance, as well as a power system swing equation. This method can be applied to a post-accident offline analysis or an online analysis. Challenges in the online analysis lies in acquiring accurate data such as a disturbance moment, a disturbance quantity and a power system frequency change rate, and filtering the data.
(3) Online assessment of power system inertia is based on data of minor disturbance events such as load changes and generator unit power output adjustments, or random power fluctuations. This inertia calculation method relies on power system frequency transients caused by power outages. Such power generation loss events are relatively rare and usually cause significant frequency disturbances. However, post-incident studies are required to determine causes, locations, types and the like of tripping to characterize inertia and power system response. Scarcity of these events, particularly repeated similar events, makes verification of these methods become difficult. At present, such methods are still in the exploratory stage and lack practical engineering conditions.

### SUMMARY

An objective of the present disclosure is to provide a method and system for calculating system inertia based on a sliding window at a moment of fault occurrence, so as to solve at least one of the technical problems in the background art.

To achieve the above objective, the present disclosure provides a method for calculating system inertia based on a sliding window at a moment of fault occurrence, and the method includes the following steps:
when a fault occurs due to a power disturbance in the power system, acquiring a frequency of each bus of the power system, active data of tie lines, and an active power output of a generator unit from a PMU device, and calculating a capacity of the power system;
using an empirical mode decomposition method to filter the frequency of each bus after the disturbance in the power system, and employing a moving average filtering algorithm to filter a bus voltage and the active power output of the generator unit;
based on filtered frequency data of each bus of the power system, using a fixed sliding window to calculate a frequency change rate of the power system at each node, and determining a moment of fault occurrence according to the frequency change rate;
based on a filtered bus voltage, calculating a voltage fluctuation index of each bus to determine an oscillation center of the power system;
based on a frequency curve of the oscillation center of the power system, taking the determined moment of fault occurrence as a calculation start moment, continuously increasing a size of a sliding window, and calculating a frequency change rate of each window;
calculating and obtaining an inertia change curve of the power system according to the frequency change rate of each window, the active data of tie lines, the active power output of the generator unit, and the capacity of the power system; and
obtaining inertia of the power system according to the inertia change curve of the power system.

According to one aspect of the present disclosure, the determining a moment of fault occurrence according to the frequency change rate specifically means: a moment corresponding to a maximum frequency change rate is taken as the moment of fault occurrence.

According to one aspect of the present disclosure, a calculation formula for the voltage fluctuation index of each bus is:

$${V}_{i} = \frac{{\int }_{{t}_{i} - Δ t}^{{t}_{i} + Δ t} \vert {V}_{i} ( t ) - {V}_{i 0} \vert dt}{2 {V}_{i 0} Δ t} ;$$

in the formula, Vᵢ is a voltage fluctuation index of an i^{th} bus; tᵢ is a moment when a voltage of the i^{th} bus reaches an extreme value; Vᵢ₀ is a voltage of the i^{th} bus before fault occurrence; Δt is a set time threshold, usually taken as 0.1 s for the system in reality; and
the oscillation center of the power system is a bus with a maximum voltage fluctuation index.

According to one aspect of the present disclosure, the taking the determined moment of fault occurrence as a calculation start moment, continuously increasing a size of a sliding window, and calculating a frequency change rate of each window specifically mean:
the determined moment of fault occurrence is taken as the calculation start moment, the size of a sliding window is continuously increased, the frequency change rate of each window is calculated, and the calculation ends 3 s later; and
a width variation amplitude of the sliding window is a sampling interval of the PMU device, and the sampling interval is 0.02 s.

According to one aspect of the present disclosure, an inertia calculation formula for the power system is:

$${H}_{sys} = \frac{1}{2} \cdot \frac{Δ {P}_{d}}{{S}_{sys}} \cdot {f}_{0} / \frac{{df}_{coi}}{dt} ;$$

in the formula, H_{sys} is inertia of the power system;

$$\frac{{df}_{c o i}}{dt} = \frac{f ( t ) - {f}_{0}}{Δ t}$$

is a window frequency change rate; f_{coi} is an inertia center frequency; f(t) is a real-time frequency corresponding to a moment t; f₀ is a frequency at the moment of fault occurrence; ΔP_{d} is disturbance power, which is calculated according to the active data of tie lines and the active power output of the generator unit; and S_{sys} is a capacity of the power system.

According to one aspect of the present disclosure, the obtaining inertia of the power system according to the inertia change curve of the power system specifically means:
a minimum value of the inertia change curve of the power system is selected as the inertia of the power system.

To achieve the above objective, the present disclosure further provides a system for calculating system inertia based on a sliding window at a moment of fault occurrence, and the system includes: a data acquisition module, configured for acquiring a frequency of each bus of the power system, active data of tie lines, and an active power output of a generator unit from a PMU device, and calculating a capacity of the power system when a fault occurs due to a power disturbance in the power system;
a data preprocessing module, configured for using an empirical mode decomposition method to filter the frequency of each bus after the disturbance in the power system, and employing a moving average filtering algorithm to filter a bus voltage and the active power output of the generator unit;
a fault moment identification module, configured for using a fixed sliding window to calculate a frequency change rate of the power system at each node based on filtered frequency data of each bus of the power system, and determining a moment of fault occurrence according to the frequency change rate;
an oscillation center determination module, configured for calculating a voltage fluctuation index of each bus based on a filtered bus voltage, to determine an oscillation center of the power system;
a window frequency change rate calculation module, configured for taking the determined moment of fault occurrence as a calculation start moment based on a frequency curve of the oscillation center of the power system, continuously increasing a size of a sliding window, and calculating a frequency change rate of each window;
a power system inertia change curve calculation module, configured for calculating and obtaining an inertia change curve of the power system according to the frequency change rate of each window, the active data of tie lines, the active power output of the generator unit, and the capacity of the power system; and
a power system inertia confirmation module, configured for obtaining inertia of the power system according to the inertia change curve of the power system.

To achieve the above objective, the present disclosure further provides an electronic device. The electronic device includes a processor, a memory, and a computer program stored on the memory. When the computer program is executed by the processor, the method for calculating system inertia based on a sliding window at a moment of fault occurrence is implemented.

To achieve the above objective, the present disclosure further provides a computer-readable storage medium on which a computer program is stored, where when the computer program is executed by the processor, the method for calculating system inertia based on a sliding window at a moment of fault occurrence is implemented.

According to the solution of the present disclosure, the present disclosure performs system inertia identification based on a measured disturbance in the PMU device, which can overcome the defect of inaccurate inertia evaluation caused by SCADA-based grid-connected monitoring mainly employed at present. According to the solution, after a disturbance occurs, data generated before the disturbance such as the capacity of the power system, the disturbance power, the frequency and the bus voltage are filtered, and the inertia evaluation on an oscillation center frequency curve is performed based on a rotor motion equation, to realize online monitoring and identification of frequency characteristics of the power system, so as to ensure frequency safety and stability of the power system.

### BRIEF DESCRIPTION OF DRAWINGS

FIG. 1 schematically illustrates a flowchart of a method for calculating system inertia based on a sliding window at a moment of fault occurrence according to an embodiment of the present disclosure.

FIG. 2 is a bus frequency curve diagram of oscillation of a power system.

FIG. 3 is a diagram of an inertia change curve of a power system.

FIG. 4 is a diagram of a frequency response curve of a power system.

### DETAILED DESCRIPTION OF THE EMBODIMENTS

The contents of the present disclosure will now be described with reference to exemplary embodiments. It should be understood that the embodiments described are merely intended to enable those of ordinary skill in the art to better understand and thus implement the contents of the present disclosure, and do not imply any limitation as to the scope of the present disclosure.

As used herein, the terms “include” and variants thereof are to be interpreted as open-ended terms meaning “including but not limited to”. The term “on the basis of” is to be interpreted as “at least partially on the basis”. The terms “one embodiment” and “an embodiment” are to be interpreted as “at least one embodiment”.

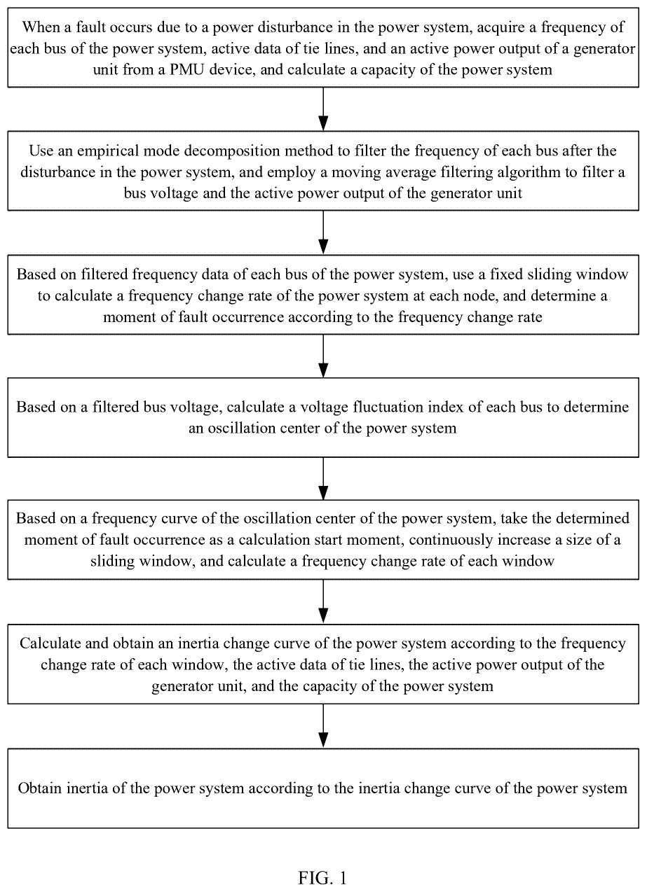

FIG. 1 schematically illustrates a flowchart of a method for calculating system inertia based on a sliding window at a moment of fault occurrence according to an embodiment of the present disclosure. As illustrated in FIG. 1, in this embodiment, the method for calculating system inertia based on a sliding window at a moment of fault occurrence includes the following steps:
when a fault occurs due to a power disturbance in the power system, acquiring a frequency of each bus of the power system, active data of tie lines, and an active power output of a generator unit from a PMU device, and calculating a capacity of the power system;
using an empirical mode decomposition method to filter the frequency of each bus after the disturbance in the power system, and employing a moving average filtering algorithm to filter a bus voltage and the active power output of the generator unit;
based on filtered frequency data of each bus of the power system, using a fixed sliding window to calculate a frequency change rate of the power system at each node, and determining a moment of fault occurrence according to the frequency change rate;
based on a filtered bus voltage, calculating a voltage fluctuation index of each bus to determine an oscillation center of the power system;
based on a frequency curve of the oscillation center of the power system, taking the determined moment of fault occurrence as a calculation start moment, continuously increasing a size of a sliding window, and calculating a frequency change rate of each window;
calculating and obtaining an inertia change curve of the power system according to the frequency change rate of each window, the active data of tie lines, the active power output of the generator unit, and the capacity of the power system; and
obtaining inertia of the power system according to the inertia change curve of the power system.

Further, according to an embodiment of the present disclosure, the determining a moment of fault occurrence according to the frequency change rate specifically means: a moment corresponding to a maximum frequency change rate is taken as the moment of fault occurrence.

Further, according to an embodiment of the present disclosure, a calculation formula for the voltage fluctuation index of each bus is:

$${V}_{i} = \frac{{\int }_{{t}_{i} - Δ t}^{{t}_{i} + Δ t} \vert {V}_{i} ( t ) - {V}_{i 0} \vert dt}{2 {V}_{i 0} Δ t} ;$$

in the formula, Vᵢ is a voltage fluctuation index of an i^{th} bus; tᵢ is a moment when a voltage of the i^{th} bus reaches an extreme value; Vᵢ₀ is a voltage of the i^{th} bus before fault occurrence; Δt is a set time threshold, usually taken as 0.1 s for the system in reality; and
the oscillation center of the power system is a bus with a maximum voltage fluctuation index.

Further, according to an embodiment of the present disclosure, the taking the determined moment of fault occurrence as a calculation start moment, continuously increasing a size of a sliding window, and calculating a frequency change rate of each window specifically mean:
the determined moment of fault occurrence is taken as the calculation start moment, the size of a sliding window is continuously increased, the frequency change rate of each window is calculated, and the calculation ends 3 s later; and
a width variation amplitude of the sliding window is a sampling interval of the PMU device, and the sampling interval is 0.02 s.

Further, according to an embodiment of the present disclosure, an inertia calculation formula for the power system is:

$${H}_{sys} = \frac{1}{2} \cdot \frac{Δ {P}_{d}}{{S}_{sys}} \cdot {f}_{0} / \frac{{df}_{coi}}{dt} ;$$

in the formula, H_{sys} is inertia of the power system;

$$\frac{{df}_{c o i}}{dt} = \frac{f ( t ) - {f}_{0}}{Δ t}$$

is a window frequency change rate; f_{coi} is an inertia center frequency; f(t) is a real-time frequency corresponding to a moment t; f₀ is a frequency at the moment of fault occurrence; ΔP_{d} is disturbance power, which is calculated according to the active data of tie lines and the active power output of the generator unit; and S_{sys} is a capacity of the power system.

Further, according to an embodiment of the present disclosure, the obtaining inertia of the power system according to the inertia change curve of the power system specifically means:
a minimum value of the inertia change curve of the power system is selected as the inertia of the power system.

According to the above solution of the present disclosure, the present disclosure performs system inertia identification based on a measured disturbance in the PMU device, which can overcome the defect of inaccurate inertia evaluation caused by SCADA-based grid-connected monitoring mainly employed at present. According to the solution, after a disturbance occurs, data generated before the disturbance such as the capacity of the power system, the disturbance power, the frequency and the bus voltage are filtered, and the inertia evaluation on an oscillation center frequency curve is performed based on a rotor motion equation, to realize online monitoring and identification of frequency characteristics of the power system, so as to ensure frequency safety and stability of the power system.

Further, the present disclosure further provides a system for calculating system inertia based on a sliding window at a moment of fault occurrence, and the system includes:
a data acquisition module, configured for acquiring a frequency of each bus of the power system, active data of tie lines, and an active power output of a generator unit from a PMU device, and calculating a capacity of the power system when a fault occurs due to a power disturbance in the power system;
a data preprocessing module, configured for using an empirical mode decomposition method to filter the frequency of each bus after the disturbance in the power system, and employing a moving average filtering algorithm to filter a bus voltage and the active power output of the generator unit;
a fault moment identification module, configured for using a fixed sliding window to calculate a frequency change rate of the power system at each node based on filtered frequency data of each bus of the power system, and determining a moment of fault occurrence according to the frequency change rate;
an oscillation center determination module, configured for calculating a voltage fluctuation index of each bus based on a filtered bus voltage, to determine an oscillation center of the power system;
a window frequency change rate calculation module, configured for taking the determined moment of fault occurrence as a calculation start moment based on a frequency curve of the oscillation center of the power system, continuously increasing a size of a sliding window, and calculating a frequency change rate of each window;
a power system inertia change curve calculation module, configured for calculating and obtaining an inertia change curve of the power system according to the frequency change rate of each window, the active data of tie lines, the active power output of the generator unit, and the capacity of the power system; and
a power system inertia confirmation module, configured for obtaining inertia of the power system according to the inertia change curve of the power system.

Further, according to an embodiment of the present disclosure, the determining a moment of fault occurrence according to the frequency change rate specifically means: a moment corresponding to a maximum frequency change rate is taken as the moment of fault occurrence.

Further, according to an embodiment of the present disclosure, a calculation formula for the voltage fluctuation index of each bus is:

$${V}_{i} = \frac{{\int }_{{t}_{i} - Δ t}^{{t}_{i} + Δ t} \vert {V}_{i} ( t ) - {V}_{i 0} \vert dt}{2 {V}_{i 0} Δ t} ;$$

in the formula, Vᵢ is a voltage fluctuation index of an i^{th} bus; tᵢ is a moment when a voltage of the i^{th} bus reaches an extreme value; Vᵢ₀ is a voltage of the i^{th} bus before fault occurrence; Δt is a set time threshold, usually taken as 0.1 s for the system in reality; and
the oscillation center of the power system is a bus with a maximum voltage fluctuation index.

Further, according to an embodiment of the present disclosure, the taking the determined moment of fault occurrence as a calculation start moment, continuously increasing a size of a sliding window, and calculating a frequency change rate of each window specifically mean:
the determined moment of fault occurrence is taken as the calculation start moment, the size of a sliding window is continuously increased, the frequency change rate of each window is calculated, and the calculation ends 3 s later; and
a width variation amplitude of the sliding window is a sampling interval of the PMU device, and the sampling interval is 0.02 s.

Further, according to an embodiment of the present disclosure, a calculation formula for system inertia is:

$${H}_{sys} = \frac{1}{2} \cdot \frac{Δ {P}_{d}}{{S}_{sys}} \cdot {f}_{0} / \frac{{df}_{coi}}{dt} ;$$

in the formula, H_{sys} is inertia of the power system;

$$\frac{{df}_{c o i}}{dt} = \frac{f ( t ) - {f}_{0}}{Δ t}$$

is a window frequency change rate; f_{coi} is an inertia center frequency; f(t) is a real-time frequency corresponding to a moment t; f₀ is a frequency at the moment of fault occurrence; ΔP_{d} is disturbance power, which is calculated according to the active data of tie lines and the active power output of the generator unit; and S_{sys} is a capacity of the power system.

Further, according to an embodiment of the present disclosure, the obtaining inertia of the power system according to the inertia change curve of the power system specifically means:
a minimum value of the inertia change curve of the power system is selected as the inertia of the power system.

According to the above solution of the present disclosure, the present disclosure performs system inertia identification based on a measured disturbance in the PMU device, which can overcome the defect of inaccurate inertia evaluation caused by SCADA-based grid-connected monitoring mainly employed at present. According to the solution, after a disturbance occurs, data generated before the disturbance such as the capacity of the power system, the disturbance power, the frequency and the bus voltage are filtered, and the inertia evaluation on an oscillation center frequency curve is performed based on a rotor motion equation, to realize online monitoring and identification of frequency characteristics of the power system, so as to ensure frequency safety and stability of the power system.

Further, the present disclosure further provides an electronic device. The electronic device includes a processor, a memory, and a computer program stored on the memory. When the computer program is executed by the processor, the method for calculating system inertia based on a sliding window at a moment of fault occurrence is implemented.

Further, the present disclosure further provides a computer-readable storage medium on which a computer program is stored, where when the computer program is executed by the processor, the method for calculating system inertia based on a sliding window at a moment of fault occurrence is implemented.

Based on the above solution of the present disclosure, the solution of the present disclosure is described in detail below in combination with the accompanying drawings in the form of a specific example.

### Example 1

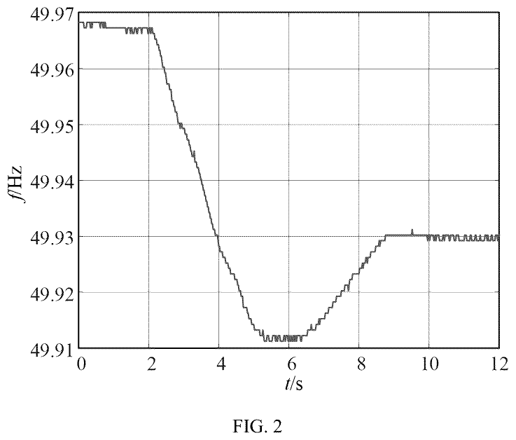

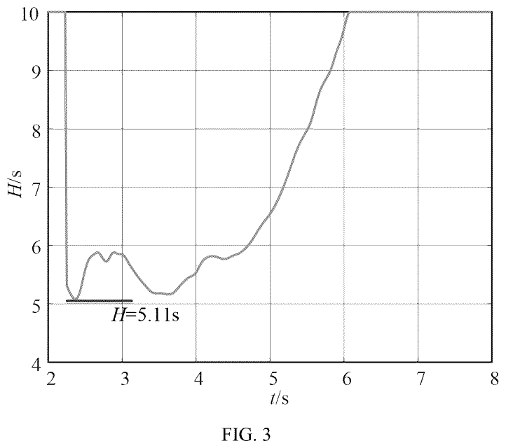

A tripping event of a generator unit in a power grid is taken as an example, and a disturbance that occurs to the power grid is analyzed. A method for calculating system inertia based on a sliding window at a moment of fault occurrence includes the following steps:
S1: acquisition of measured data: an active power output of the unit before occurrence of the tripping fault is 400 MW, a base capacity is 72775 MVA, and inertia of the power system obtained based on SCADA grid-connected synchronous generator evaluation is 4.34 s;
S2: data preprocessing: an empirical mode decomposition method is used to filter a frequency of each bus after the disturbance in the power system in the S1, and a moving average filtering algorithm is employed to filter a bus voltage and the active power output of the unit;
S3: fault moment identification: a fixed sliding window is used to calculate a frequency change rate of the power system at each node based on frequency data of each bus of the power system, and a moment of fault occurrence is determined according to the frequency change rate, where the moment of fault occurrence is t₀=2.0 s;
S4: oscillation center identification: a voltage fluctuation index of each bus is calculated to determine an oscillation center of the power system, where a frequency curve of power system oscillation is illustrated in FIG. 2;
S5: inertia evaluation based on a sliding window at the moment of fault occurrence: based on the frequency curve of the oscillation center of the power system obtained in the S4, the moment of fault occurrence (t₀=2.0 s) determined in the S3 is taken as a calculation start moment, a size of the sliding window is continuously increased, and a frequency change rate of each window is calculated to obtain an inertia change curve of the power system, as illustrated in FIG. 3;
a specific calculation formula is:

$${H}_{sys} = \frac{1}{2} \cdot \frac{Δ {P}_{d}}{{S}_{sys}} \cdot {f}_{0} / \frac{{df}_{coi}}{dt} ;$$

in the formula, f_{coi} is an inertia center frequency; f(t) is a real-time frequency corresponding to a moment t; f₀ is a frequency at the moment of fault occurrence; ΔP_{d} is disturbance power, ΔP_{d} is calculated according to the active data of tie lines and the active power output of the unit in the S1; H_{sys} is inertia of the power system; S_{sys} is a capacity of the power system; and

$$\frac{{df}_{c o i}}{dt} = \frac{f ( t ) - {f}_{0}}{Δ t}$$

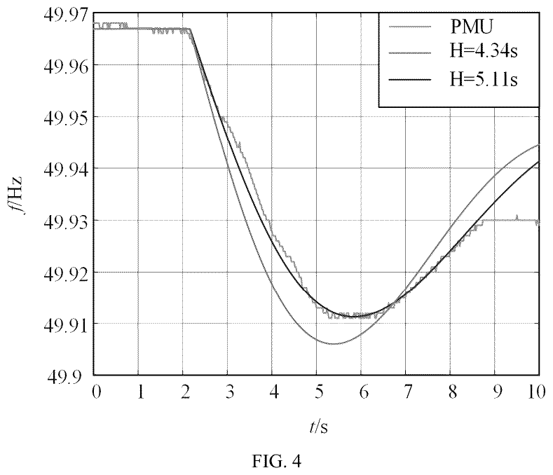

is a window frequency change rate; and
S6: power system inertia characterization: a minimum value of the inertia change curve of the power system in the S5 is selected as the inertia of the power system, and as illustrated in FIG. 4, H (the inertia of the power system) is equal to 5.11 s.

Based on an equivalent swing equation for the power system, frequency characteristics of the power system after a power disturbance are analyzed by use of different inertia time constants, and compared with the measured data. Specifically, an active disturbance quantity ΔP=400 MW is taken as a constant, and frequency response curves of the power system are calculated when H=4.34 s (i.e., the inertia of the power system obtained based on actual measurement by the SCADA grid-connected synchronous generator) and H=5.11 s (the inertia of the power system obtained based on the calculation method of the present disclosure), and compared with a measured PMU frequency curve of the power grid. The results are shown in FIG. 4. A frequency response curve of the power system calculated based on the inertia of the power system obtained according to the calculation method of the present disclosure is basically consistent with a measured inertia center frequency curve (the measured PMU frequency curve). However, a frequency response curve of the power system calculated based on the inertia of the power system obtained from the SCADA grid-connected synchronous generator evaluation deviates significantly from the measured inertia center frequency curve (the measured PMU frequency curve). It can be seen that the inertia of the power system obtained according to the calculation method of the present disclosure is more accurate and precise.

Those of ordinary skill in the art may appreciate that the modules and algorithm steps described in combination with the embodiments disclosed herein can be implemented in electronic hardware, or a combination of computer software and electronic hardware. Whether these functions are performed in electronic hardware or software depends on the specific application and design constraints of the technical solution. Those skilled in the art can use different methods to implement the described functions for each particular application, but such implementation should not be considered to be beyond the scope of the present disclosure.

Those skilled in the art can clearly understand that, for convenience and brevity of description, specific working processes of the above-described apparatus and device may refer to corresponding processes in the foregoing method embodiments, and are not repeated herein.

In the embodiments provided by the present disclosure, it should be understood that the disclosed apparatus and method may be implemented in other ways. For example, the apparatus embodiments described above are merely schematic. For example, division of modules is merely a kind of division of logic functions, there may be other division modes in actual implementation, and for example, a plurality of modules or assemblies may be combined or integrated into another system, or some features may be omitted or not conducted. Furthermore, shown or discussed coupling or direct coupling or communication connection between each other may be an indirect coupling or communication connection by means of an interface, an apparatus or a module, and may be in an electrical, mechanical or other form.

The module described as a separable part may be physically separated or not, and a part shown as a module may be a physical module or not, that is, may be located at one place or may also be distributed on a plurality of network modules. Part or all of the modules may be selected according to actual needs to achieve the objective of the solution of the embodiments of the present disclosure. In addition, the functional modules in the embodiments of the present disclosure may be integrated into one processing module, or each module may be physically present separately, or two or more modules may be integrated into the one module.

If the functions are implemented in the form of the software functional modules and sold or used as independent products, they may be stored in a computer readable storage medium. On the basis of such understanding, the technical solution of the present disclosure, in essence or from the view of part contributing to the prior art, or part of the technical solution may be embodied in the form of a computer software product that is stored in a storage medium and includes a plurality of instructions configured to make one computer device (which may be a personal computer, a server or a network device, etc.) conduct all or part of the steps of the single-phase-to-ground protection method for an active power distribution network in each of the embodiments of the present disclosure. The foregoing storage medium includes various media which may store program codes, such as a universal serial bus (USB) flash drive, a mobile hard disk drive, a read-only memory (ROM), a random access memory (RAM), a diskette and an optical disk.

The above description is merely illustrative of preferred embodiments of the present disclosure and of principles of the technology employed. It should be understood by those skilled in the art that the scope of the invention referred to in the present disclosure is not limited to the technical solutions in which the above-described technical features are specifically combined, but also encompasses other technical solutions in which the above-described technical features or equivalent features thereof are arbitrarily combined without departing from the inventive concept, for example, technical solutions formed by interchanging the features described above with (but not limited to) technical features disclosed in the present disclosure that have similar functions.

It should be understood that the sequence number of each step in the contents of the present disclosure and the embodiments of the present disclosure does not absolutely mean the order of execution, and the execution order of each process should be determined by its function and internal logic, and should not constitute any limitation on the implementation process of the embodiments of the present disclosure.

1. A computer-implemented method for configuring a power system based on inertia of the power system, the power system comprising a generator unit, a PMU device, buses and tie lines, wherein the computer-implemented method comprises:
when a fault occurs due to a power disturbance in the power system, acquiring a frequency of each bus of the power system, active data of the tie lines, and an active power output of the generator unit from the PMU device, and calculating a capacity of the power system;
using an empirical mode decomposition method to filter the frequency of each bus after the disturbance in the power system, and employing a moving average filtering algorithm to filter a bus voltage and the active power output of the generator unit;
based on filtered frequency data of each bus of the power system, using a fixed sliding window to calculate a frequency change rate of the power system at each node, and determining a moment of fault occurrence according to the frequency change rate;
based on a filtered bus voltage, calculating a voltage fluctuation index of each bus to determine an oscillation center of the power system;
based on a frequency curve of the oscillation center of the power system, taking the determined moment of fault occurrence as a calculation start moment, continuously increasing a size of a sliding window, and calculating a frequency change rate of each window;
calculating and obtaining an inertia change curve of the power system according to the frequency change rate of each window, the active data of the tie lines, the active power output of the generator unit, and the capacity of the power system;
obtaining inertia of the power system according to the inertia change curve of the power system; and
configuring the power system based on the obtained inertia to maintain frequency stability of the power system;
wherein a calculation formula for the voltage fluctuation index of each bus is:
$${V}_{i} = \frac{{\int }_{{t}_{i} - Δ t}^{{t}_{i} + Δ t} \vert {V}_{i} ( t ) - {V}_{i 0} \vert dt}{2 {V}_{i 0} Δ t} ;$$
in the formula, Vᵢ is a voltage fluctuation index of an i^{th} bus; tᵢ is a moment when a voltage of the i^{th} bus reaches an extreme value: Vᵢ₀ is a voltage of the i^{th} bus before fault occurrence: Δt is a set time threshold, usually taken as 0.1 s for the power system in reality; and
the oscillation center of the power system is a bus with a maximum voltage fluctuation index,
an inertia calculation formula for the power system is:
$${H}_{sys} = \frac{1}{2} \cdot \frac{Δ {P}_{d}}{{S}_{sys}} \cdot {f}_{0} / \frac{{df}_{coi}}{dt} ;$$
in the formula, H_{sys} is inertia of the power system;
$$\frac{{df}_{c o i}}{dt} = \frac{f ( t ) - {f}_{0}}{Δ t}$$
is a window frequency change rate; f_{coi} is an inertia center frequency; f(t) is a real-time frequency corresponding to a moment t; f₀ is a frequency at the moment of fault occurrence; ΔP_{d} is disturbance power, which is calculated according to the active data of tie lines and the active power output of the generator unit; and S_{sys} is a capacity of the power system.

2. The computer-implemented method according to claim 1, wherein the determining a moment of fault occurrence according to the frequency change rate specifically means: a moment corresponding to a maximum frequency change rate is taken as the moment of fault occurrence.

3. (canceled)

4. The computer-implemented method according to claim 1, wherein the taking the determined moment of fault occurrence as a calculation start moment, continuously increasing a size of a sliding window, and calculating a frequency change rate of each window specifically mean:
the determined moment of fault occurrence is taken as the calculation start moment, the size of a sliding window is continuously increased, the frequency change rate of each window is calculated, and the calculation ends 3 s later; and
a width variation amplitude of the sliding window is a sampling interval of the PMU device, and the sampling interval is 0.02 s.

5. (canceled)

6. The computer-implemented method according to claim 1, wherein the obtaining inertia of the power system according to the inertia change curve of the power system specifically means:
a minimum value of the inertia change curve of the power system is selected as the inertia of the power system.

7. (canceled)

8. An electronic device, comprising: a processor, a memory, and a computer program which is stored on the memory and is runnable on the processor, wherein when the computer program is executed by the processor, the method for configuring a power system based on inertia of the power system according to claim 1 is implemented.

9. A non-transitory computer-readable storage medium on which a computer program is stored, wherein when the computer program is executed by the processor, the method for configuring a power system based on inertia of the power system according to claim 1 is implemented.
